(19) United States
(12) Patent Application Publication
(10) Pub. No.: US 2025/0274127 A1
(43) Pub. Date: Aug. 28, 2025

(54) LOGIC GATE COMPLEXITY

(71) Applicant: Arm Limited, Cambridge (GB)

(72) Inventor: Thomas ELMER, Austin, TX (US)

(21) Appl. No.: 18/590,046

(22) Filed: Feb. 28, 2024

(51) Int. Cl. H03K 19/20; G06F 7/508

(52) U.S. Cl. CPC H03K 19/20; G06F 7/508

(57) ABSTRACT

A plurality of logic gates are used in an addition of a first vector of bits to a second vector of bits, the plurality of logic gates receive four inputs: a generate signal indicating whether the addition at a first bit position would unconditionally produce a carry-out signal at the first bit position; a propagate signal indicating whether the addition at a second bit position would conditionally produce a carry-out signal at the second bit position; an at least partial generate star signal indicating whether at least one of the following conditions is met: the addition at any of least significant bit positions of the first vector and the second vector would conditionally produce a carry-out signal at a most significant bit position of the first vector and the second vector, or the addition at the most significant bit position of the first vector and the second vector would unconditionally produce a carry-out signal; and an at least partial propagate star signal indicating whether the addition at each of least significant bit positions of the first vector and the second vector would conditionally produce a carry-out signal at the most significant bit position of the first vector and the second vector. The logic gates combine the four inputs to indicate whether the addition at most significant bit positions of the first vector and the second vector will unconditionally and/or conditionally produce a carry-out signal.

### TECHNICAL FIELD

The present disclosure relates to data processing and particularly the size and delay of circuits.

### DESCRIPTION

In data processing apparatuses, it is generally desirable to perform operations quickly. Operations can often be parallelised. However, this can lead to an increase in the number of logic gates that are required, which increases the size of the circuitry and thereby the power that is drawn and it is generally desirable to decrease both circuit size and power draw. It would therefore be preferable to provide circuits that operate quickly (i.e. with a low delay) while keeping the resulting circuit size small.

### SUMMARY

Viewed from a first example configuration, there is provided an apparatus comprising: a plurality of logic gates used in an addition of a first vector of bits to a second vector of bits, the plurality of logic gates being configured to receive four inputs comprising: a generate signal configured to indicate whether the addition at a first bit position would unconditionally produce a carry-out signal at the first bit position; a propagate signal configured to indicate whether the addition at a second bit position would conditionally produce a carry-out signal at the second bit position; an individual partial generate star signal configured to indicate whether the addition of the first vector and the second vector at a third bit position or a fourth bit position would unconditionally produce a carry-out signal at either of the third bit position or the fourth bit position; and an individual partial propagate star signal configured to indicate whether the addition of the first vector and the second vector at a fifth bit position and a sixth bit position would conditionally produce carry-out signals at the fifth bit position and the sixth bit position, wherein the plurality of logic gates are configured to combine the four inputs to output an indication of whether the addition at most significant bit positions of the first vector and the second vector will unconditionally produce a carry-out signal and to output an indication of whether the addition at least significant bit positions of the first vector and the second vector will conditionally produce a carry-out signal.

Viewed from a second example configuration, there is provided a non-transitory computer-readable medium storing computer-readable code for fabrication of an apparatus comprising: a plurality of logic gates used in an addition of a first vector of bits to a second vector of bits, the plurality of logic gates being configured to receive four inputs comprising: a generate signal configured to indicate whether the addition at a first bit position would unconditionally produce a carry-out signal at the first bit position; a propagate signal configured to indicate whether the addition at a second bit position would conditionally produce a carry-out signal at the second bit position; an individual partial generate star signal configured to indicate whether the addition of the first vector and the second vector at a third bit position or a fourth bit position would unconditionally produce a carry-out signal at either of the third bit position or the fourth bit position; and an individual partial propagate star signal configured to indicate whether the addition of the first vector and the second vector at a fifth bit position and a sixth bit position would conditionally produce carry-out signals at the fifth bit position and the sixth bit position, wherein the plurality of logic gates are configured to combine the four inputs to output an indication of whether the addition at most significant bit positions of the first vector and the second vector will unconditionally produce a carry-out signal and to output an indication of whether the addition at least significant bit positions of the first vector and the second vector will conditionally produce a carry-out signal.

Viewed from a third example configuration, there is provided carry-lookahead circuitry comprising: a plurality of logic nodes logically arranged in a plurality of layers, each of the logic nodes performing a logical function using a plurality of interconnected logic gates, wherein the logic nodes of one layer receive at least one input from an immediately previous one of the plurality of layers; a first logical layer of the plurality of layers is configured to receive, in respect of each bit position for a first vector of bits and a second vector of bits: a generate signal configured to indicate whether bits of the first vector and the second vector at that bit position would unconditionally produce a carry-out signal, and a propagate signal configured to indicate whether bits of the first vector and the second vector at that bit position would conditionally produce a carry-out signal; the first logical layer of the plurality of layers is configured to have one of the logic nodes at every second bit position; and a second logical layer of the plurality of layers is configured to have one of the logic nodes at every fourth bit position and to have one of the logic nodes at a position one bit before every fourth bit position; the carry-lookahead circuitry comprises a plurality of tiles, each comprising the plurality of logic nodes arranged as the first logical layer and the second logical layer, wherein each of the tiles is configured to process 4 bits of the first vector of bits and the second vector of bits; each of the tiles comprises (log₂(M)−2) further layers after the second logical layer, where M is a number of bits in a largest of the first vector of bits and the second vector of bits; and each of the further layers reduces a number of outputs from a preceding layer to provide as inputs to a subsequent layer.

Viewed from a fourth example configuration, there is provided a system comprising: the apparatus, the adder circuit, or the carry-lookahead circuitry as previously described, implemented in at least one packaged chip; at least one system component; and a board, wherein the at least one packaged chip and the at least one system component are assembled on the board.

Viewed from a fifth example configuration, there is provided a chip-containing product comprising the system as previously described, wherein the system is assembled on a further board with at least one other product component.

### BRIEF DESCRIPTION OF THE DRAWINGS

The present invention will be described further, by way of example only, with reference to embodiments thereof as illustrated in the accompanying drawings, in which:

FIG. 1 shows the addition of two vectors of bits A, B;

FIG. 2A shows a circuit diagram that illustrates how a carry-out signal can be determined at a bit position x;

FIG. 2B illustrates a different representation of the circuitry of FIG. 2A;

FIG. 3A shows a generalisation of the circuitry shown in FIG. 2A;

FIG. 3B shows an alternative representation of the circuitry of FIG. 3A;

FIG. 4A illustrates an apparatus 16;

FIG. 4B illustrates a different representation of the circuitry of FIG. 4A;

FIG. 4C illustrates an alternative implementation of the apparatus 16;

FIG. 4D illustrates a different representation of the circuitry of FIG. 4C;

FIG. 4E illustrates an alternative implementation of the apparatus 16;

FIG. 4F illustrates a different representation of the circuitry of FIG. 4E;

FIG. 5A illustrates the apparatus 16 of FIG. 4A in the context of an adder circuit;

FIG. 5B illustrates another representation of the circuitry of FIG. 5A;

FIG. 5C illustrates the apparatus 16 of FIG. 4C in the context of an adder circuit;

FIG. 5D illustrates another representation of the circuitry of FIG. 5C;

FIG. 5E illustrates the apparatus 16 of FIG. 4E in the context of an adder circuit;

FIG. 5F illustrates another representation of the circuitry of FIG. 5E;

FIG. 6 illustrates another example in which the apparatus is used in adder circuitry;

FIG. 7 shows an alternative implementation of the adder circuitry;

FIG. 8 shows a non-Ling diagrammatic variant of the adder circuitry shown in FIG. 6; and

FIG. 9 shows the other non-Ling diagrammatic variant 36 of the adder circuitry 32 shown in FIG. 7; and

FIG. 10 shows one or more packaged chips, with the apparatus and/or adder.

### DESCRIPTION OF EXAMPLE EMBODIMENTS

A previously proposed approach to performing addition of numbers in circuits is to address each pair of bits one at a time, from least significant bit to most significant bit. In each case, the bits at a given position (together with the result of any incoming carry) indicates the output value. As a consequence of this, determining the addition at any given bit position requires all preceding bit positions to be calculated first in order to determine whether the given bit position has an incoming carry or not. This makes the process slow for large inputs. For instance, adding two 64-bit numbers requires the process to be iterated 64 times. An improvement to this process can be achieved using carry look-ahead adders, which is where, for each bit, it is determined whether the bits at each bit position conditionally (p) produce a carry-out value or if they unconditionally (g) produce a carry-out value. For instance, if exactly one of the bits at a given bit position is 1 then whether or not there will be a carry-out value is dependent on whether a value is carried in. If both of the bits at a given bit position are 1 then there will always be a carry-out value. From this, one can work out whether any given digit will output a carry-out value. In particular, a given bit position will generate a carry-out value either if it does so unconditionally (its own position is ‘g’) or if it does so conditionally (its own position is ‘p’) and the preceding bit position generates a carry-out value (either the preceding bit position ‘g’ or alternatively it is ‘p’ and its preceding bit position is ‘g’). Thus, whether or not a carry is produced at a given bit position can be determined by as large sequence of logic gates. In practice, however, this technique has poor scalability with extremely large networks of logic gates needed. There are a number of ways of combining the ‘g’ and ‘p’ signals across the bits, which have an impact on the number of gates, scalability, overall execution time, and so on.

Before discussing the embodiments with reference to the accompanying figures, the following description of embodiments is provided.

In accordance with some example configurations there is provided an apparatus comprising: a plurality of logic gates used in an addition of a first vector of bits to a second vector of bits, the plurality of logic gates being configured to receive four inputs comprising: a generate signal configured to indicate whether the addition at a first bit position would unconditionally produce a carry-out signal at the first bit position; a propagate signal configured to indicate whether the addition at a second bit position would conditionally produce a carry-out signal at the second bit position; an individual partial generate star signal configured to indicate whether the addition of the first vector and the second vector at a third bit position or a fourth bit position would unconditionally produce a carry-out signal at either of the third bit position or the fourth bit position; and an individual partial propagate star signal configured to indicate whether the addition of the first vector and the second vector at a fifth bit position and a sixth bit position would conditionally produce carry-out signals at the fifth bit position and the sixth bit position, wherein the plurality of logic gates are configured to combine the four inputs to output an indication of whether the addition at most significant bit positions of the first vector and the second vector will unconditionally produce a carry-out signal and to output an indication of whether the addition at least significant bit positions of the first vector and the second vector will conditionally produce a carry-out signal.

The above examples provide an apparatus in the form of a plurality of interconnected logic gates. Logic gates take one or more (typically binary) inputs and provide a (typically binary) output based on a Boolean function (e.g. AND, OR, NOT, XOR, or a combination thereof). The logic gates are interconnected so that outputs from some of the logic gates are directly provided as inputs to others of the logic gates. The apparatus can be used in adder circuitry that is used to add a first vector of bits representing binary digits to a second vector of bits representing binary digits. For instance, the binary vectors [0,1,1,1,0,0,1,1] and [0,0,0,1,1,1,0,1] can be added together in order to achieve the addition 115+29=144. Of course, there is no requirement that the bits within the vectors have any specific values. For instance, if this were interpreted as a sub range of a larger vector then the least significant bit of the vectors being added together might represent the value 256. Thus, the apparatus may receive only some of the bits of an overall addition that is being performed. In addition to receiving a generate signal (g) that indicates whether a given bit position unconditionally produces a carry-out signal at a first bit position, and a propagate signal (p) that indicates whether a given bit position conditionally produces a carry-out signal at a second bit position, the logic gates also receive an individual partial generate star signal and an individual partial propagate star signal. The individual partial generate signal, also known as g*, is used to indicate whether the addition of the first vector and the second vector at third or fourth bit positions will conditionally produce a carry-out signal at either of those bit positions. That is, whether either of those bit positions has a value of g=1. Note that in this case, the partial generate signal is individual so that it does not provide an indication beyond the third or fourth bit positions. That is, the signal is not G*. The individual partial propagate signal, also known as p*, is used to indicate whether the addition of the first vector and the second vector at fifth and sixth bit positions unconditionally produces a carry-out signal at either of those bit positions. That is, whether both of those bit positions has a value of p=1. Note that in this case, the partial propagate signal is individual so that it does not provide an indication beyond the third or fourth bit positions. That is, the signal is not P*. Using a series of logic gates that process these signals as described above, it is possible to combine the apparatus as part of an adder that enable an addition to be performed using a comparatively small number of logic gates for the processing time in which an addition can be performed. In particular, as compared to other adder circuits, the number of other nodes can be reduced, leading to an adder that operates using a smaller circuit area.

In some examples, the second bit position is immediately prior to the first bit position. That is, if the first position is a bit x then the second bit position is a position x−1.

In some examples, the third bit position is the same as the second bit position; and the fourth bit position is immediately prior to the third bit position. So if the third bit position is a position x then the second bit position is also bit number x and the fourth bit position is a position x−1.

In some examples, the fifth bit position is the same as the fourth bit position; and the sixth bit position is immediately prior to the fifth bit position. So if the fifth bit position is a position x then the fourth bit position is also bit number x and the sixth bit position is a position x−1.

In some examples, the plurality of logic gates are configured to receive at most the generate signal, the propagate signal, the individual partial generate star signal, and the individual partial propagate star signal. That is, no other signals are received by the logic gates and so the overall complexity of the apparatus can be kept comparatively low. Of course, a larger circuit (such as an adder circuit) that includes the plurality of logic gates may itself receive other signals. Such signals are not, however, received by the plurality of logic gates.

In some examples the first vector of bits represent a first number and the second vector of bits represent a second number, with the addition operation being configured to add the first number and the second number together by adding the first vector of bits to the second vector of bits.

In some examples, the plurality of logic gates are configured to receive the generate signal, the propagate signal, the individual partial generate star signal, and the individual partial propagate star signal as inputs from outside the plurality of logic gates. In these examples, the four described signals do not originate from within the apparatus (although they may be propagated within the apparatus) and originate from outside the apparatus—such as another set of logic gates.

In some examples, the plurality of logic gates is configured to perform: a first AND function between the propagate signal and the individual partial generate star signal, a first inclusive OR function between a result of the first AND function and the generate signal, and a second AND function between the propagate signal and the individual partial propagate star signal to output the indication of whether the addition at most significant bit positions of the first vector and the second vector will unconditionally produce the carry-out signal and to output the indication of whether the addition at least significant bit positions of the first vector and the second vector will conditionally produce the carry-out signal. Note that in practice, although each of these operations can be performed using a single logic gate, there is no obligation for this to be so.

In some examples, the plurality of logic gates is configured to perform at most the first AND function, the second AND function, and the first inclusive OR function to output the indication of whether the addition at most significant bit positions of the first vector and the second vector will unconditionally produce the carry-out signal and to output the indication of whether the addition at least significant bit positions of the first vector and the second vector will conditionally produce the carry-out signal. In these examples, no further functions are performed in order to provide the two specified indications and consequently the two indications can be produced using a small number of logic gates.

In some examples, the apparatus (in any of the forms previously described) is provided as part of an adder circuit, wherein the adder circuit is configured as a plurality of layers, with each layer other than a first layer performing an operation in parallel on different inputs from a previous layer; and the first layer is configured to generate the generate signal and the propagate signal for each bit position of the first vector of bits and the second vector of bits. As previously explained, by providing the apparatus as part of an adder circuit, it is possible to achieve a good level of processing speed while using a comparably small number of logic gates.

In some examples, the adder circuit is configured as a plurality of layers, with each layer other than a first layer performing an operation in parallel on different inputs from a previous layer; and the first layer is configured to generate the generate signal and the propagate signal for each bit position of the first vector of bits and the second vector of bits. So in a first layer, the generate and propagate signals can be output. Then in a next layer, the generate and propagate signals can be processed in order to output further signals. At a next layer, any of the previously output signals can be processed to produce still further signals. Each layer can be thought of as performing one (or more) operations, with each operation being performed using different inputs from the previous layer(s). For instance, the fifth layer might perform an AND operation between a generate signal and a propagate signal generated by the first layer. Each time the AND operation is performed, different inputs are received. For instance, a first AND operation might be performed between the third and fourth bits, a second AND operation might be performed between the sixth and seventh bits, and so on. Note that, in practice, a particular circuit may be configured in the specified manner by being designed in that manner. The fabricated circuit might be different to what is designed, yet be logically equivalent due to transformations provided by synthesis tools.

In some examples, a second layer of the plurality of layers comprises one or more partial carry nodes, configured to generate the individual partial generate star signal and the individual partial propagate star signal. The partial carry nodes produce a pair of signals—a first signal (the individual partial generate star signal) indicates whether either of two adjacent bit positions will unconditionally produce a carry-out signal. That is, whether either of two adjacent bit positions have g=1. The other signal (the individual partial propagate star signal) that is produced is an indication of whether both of two bit positions (that might be the same or different to the bit positions used to produce the first signal) conditionally produce (e.g. propagate) a carry-out signal. That is, whether both of those two adjacent bit positions have p=1.

In some examples, the second layer of the plurality of layers comprises at least some holes in place of the one or more partial carry nodes such that the generate signal and the propagate signal for at least some pairs of adjacent bit positions are not provided together, as a pair of inputs, to the one or more partial carry nodes. In the second layer, there may be one or more partial carry nodes. As an alternative to the partial carry nodes, the layer may contain ‘holes’. Consequently, not every combination of adjacent bit positions is passed in to a partial carry node.

In some examples, the generate signal and the propagate signal for each of the bit positions is provided to the one or more partial carry nodes. Although not every combination of two adjacent bit positions may be used to provide propagate and generate signals to partial carry nodes, each bit position can be provided to one partial carry node. For instance, signals from the first and second bit positions might be provided to one partial carry node and signals from the third and fourth bit positions might be provided to another partial carry node. In this way, each of the first, second, third, and fourth bit positions have their signals provided to partial carry nodes. However, not every single combination of adjacent bit positions have their signals provided to partial carry nodes. For instance, the combination of the second and third bit positions is not considered.

In some examples, for at least some bit positions, the generate signal or the propagate signal are provided to exactly one of the partial carry nodes. In some embodiments, both are provided to exactly one of the partial carry nodes. In either case, in these examples, the generate signal and the propagate signals might be provided to other nodes in the adder circuitry.

In some examples, there is provided carry-lookahead circuitry comprising: a plurality of logic nodes logically arranged in a plurality of layers, each of the logic nodes performing a logical function using a plurality of interconnected logic gates, wherein the logic nodes of one layer receive at least one input from an immediately previous one of the plurality of layers; a first logical layer of the plurality of layers is configured to receive, in respect of each bit position for a first vector of bits and a second vector of bits: a generate signal configured to indicate whether bits of the first vector and the second vector at that bit position would unconditionally produce a carry-out signal, and a propagate signal configured to indicate whether bits of the first vector and the second vector at that bit position would conditionally produce a carry-out signal; the first logical layer of the plurality of layers is configured to have one of the logic nodes at every second bit position; and a second logical layer of the plurality of layers is configured to have one of the logic nodes at every fourth bit position and to have one of the logic nodes at a position one bit before every fourth bit position; the carry-lookahead circuitry comprises a plurality of tiles, each comprising the plurality of logic nodes arranged as the first logical layer and the second logical layer, wherein each of the tiles is configured to process 4 bits of the first vector of bits and the second vector of bits; each of the tiles comprises (log 2(M)−2) further layers after the second logical layer, where M is a number of bits in a largest of the first vector of bits and the second vector of bits; and each of the further layers reduces a number of outputs from a preceding layer to provide as inputs to a subsequent layer.

For instance, the circuitry may be implemented as sparse-4 parallel prefix carry look-ahead circuitry of general width, N bits. Such an infrastructure can make use of prefix nodes that combine either the generate and propagate signals from two particular bit positions, or the outputs of other prefix nodes from particular bit positions, or a combination of outputs of other prefix nodes, generate signals and prefix signals. The circuitry is described as a series of logical layers in the sense that this is how they are planned or traditionally represented. In practice, the fabrication of a circuit may cause the nodes to be replaced in a different manner or for logic gates to be combined and/or merged. It does not, therefore, necessarily represent the physical placement of the nodes. The infrastructure described here provides a ‘graph’ having a low depth or number of parallel stages (which approximates the calculation time of the addition), a low population (which leads to a lower circuit area) and a low fan-out (which affects the time/delay at each stage). Thus, a system implementing such an infrastructure can perform additions more quickly, with a lower circuit area, and with less delay at each stage of the addition. In some examples, each of the tiles comprises at most (log₂(M)−2) further layers.

In some of these examples, those of the logic nodes in the first logical layer are configured to receive the generate signal from a same bit position as themselves q and a previous bit position q−1 and to receive the propagate signal from a bit position q−1 and a bit position q−2; and those of the logic nodes in the second logical layer are configured to receive inputs from outputs of the logic nodes in the first logical layer at a same bit position as themselves r and at a bit position r−2. As previously explained, a single (third) layer may therefore be used to combine two of the 4-bit ‘nibbles’ handled by the first layer and second layer. This combination can be achieved using a prefix node or the apparatus previously described.

Particular embodiments will now be described with reference to the figures.

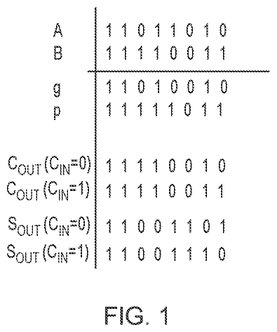

FIG. 1 shows the addition of two vectors of bits A, B where A=[1,1,0,1,1,0,1,0], B=[1,1,1,1,0,0,1,1]. At each bit position, the sum (s_{OUT}) is dependent on both the bits in that bit position of A and B as well as whether a carry-in value is provided to that bit position. For instance, at the first bit position, the value of A is 0 and the value of B is 1. The sum of these is ‘1’ unless a carry-in is provided in which case the sum will be ‘0’ and a carry-out is provided. As another example, at the second bit position, the value of A is 1 and the value of B is 1. The sum of these is ‘0’ unless a carry-in is provided in which case the sum is ‘1’.

The sum at a position [i] is therefore equal to A[i] XOR B[i] XOR C_{IN}[i]. Meanwhile, the carry at a position [i] is equal to ((A[i] AND B[i]) OR (A[i] AND C_{IN}[i]) OR (B[i] AND C_{IN}I[i])).

Meanwhile, the carry out value (C_{OUT}) may or may not be dependent on the carry-in value (C_{IN}). For example, in the above example, whether or not a carry-out signal is provided is dependent on whether a carry-in signal is provided. In contrast, at the second position, a carry-out signal is always provided regardless of whether the carry-in signal is provided—all that changes is the sum value.

In this way, it is possible to define signals g and p. In particular, if either value at a particular bit position has binary logic value 1 any carry-in value equal to binary logic value 1 will be propagated to the carry-out value, and so p=1. Otherwise p=0. If the values at a bit position are such that the carry-out value is always produced, regardless of the carry-in value then the bit position is said to generate a carry and so g=1.

It will be appreciated that if the propagation and generation state of each bit is known, then it is possible to know how far a carry will occur. For example, a carry-in will be received at a bit position x either if position x−1 generates a carry-out, or if position x−2 generates a carry-out and position x−1 propagates a carry-out. Meanwhile, a carry-in will be received at bit position x−1 either if position x−2 generates a carry-out, or if position x−3 generates a carry-out and position x−2 propagates a carry out, and so on. It is therefore possible to determine the carry status at each position using a combination of AND and OR gates and the signals g and p. This can lead to a large calculation for later (more significant) bits. Furthermore, XOR gates are comparatively slower than other types of logic gates and so calculating the sum values of more significant bits can be slow. One way to handle this is to speculatively calculate A[i] XOR B[i] XOR 0 and A[i] XOR B [i] XOR 1 and then use a multiplexer to select between these two possibilities once the carry-in value is known. This removes the calculation of A[i] XOR B[i] XOR C_{IN}[i] from the critical path.

FIG. 1 illustrates the C_{OUT} value at each bit position, assuming that a carry-in is provided to the overall vector (C_{IN}=1) and assuming that a carry-in is not provided to the overall vector (C_{IN}=0). Similarly, the S_{OUT} value at each position is illustrated, assuming that a carry-in is provided to the overall vector (C_{IN}=1) and assuming that a carry-in is not provided to the overall vector (C_{IN}=0).

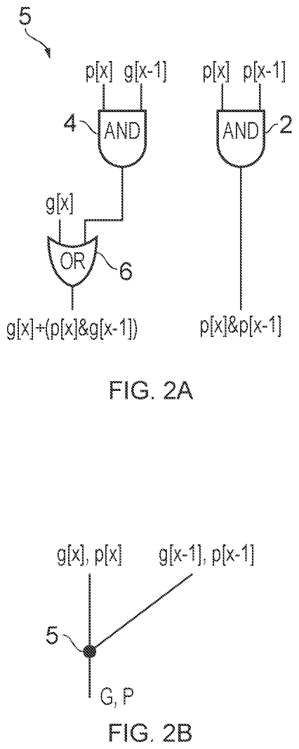

FIG. 2A shows a circuit diagram that illustrates how a carry-out signal can be determined at a bit position x using a prefix node. The logic gates take the generate signal from the current bit position g[x], the generate signal from the immediately preceding bit position g[x−1], the propagate signal from the current bit position p[x], and the propagate signal from the immediately preceding bit position p[x−1]. A logical AND gate 2 is used to perform the logical AND operation on p[x] and p[x−1] to give an indication of whether previous bit positions propagate a carry-in signal to produce a carry-out signal. A logical AND gate 4 and a logical OR gate 6 are connected hierarchically so that the logical AND gate 4 takes p[x] and g[x−1]. This determines whether the preceding bit position x−1 generates a carry-out signal unconditionally and that the current bit position x propagates it. The logical OR gate 6 then considers that output and the value g[x] and performs a logical OR operation on these two inputs to generate a signal that indicates whether the current bit position x will generate a carry-out signal. That is, either the preceding bit position x−1 generates a carry-out signal that will be propagated, or the current bit position unconditionally generates a carry-out signal.

FIG. 2B illustrates a different representation of the prefix node 5. In this figure, the generate g[x] and propagate signals p[x] for a pair of adjacent bit positions are provided to a node. The function of the node (illustrated by a circle) is equivalent to the series of logic gates 2, 4, 6 illustrated in FIG. 2A.

It will be appreciated that a series of the logic gates illustrated in FIG. 2A can be provided. For instance, in the case of a 3-bit addition, a carry-out is produced at the most-significant bit position if either: (i) the most significant bit position unconditionally produces a carry-out signal, (ii) the second most significant bit position unconditionally produces a carry-out signal and the most significant bit position propagates a carry signal, or (iii) the third most significant bit position unconditionally produces a carry-out signal and both the most significant and second most significant bit positions propagate the carry signal.

Then by knowing whether, at each bit position, a carry signal will be generated and by knowing the bit values of A and B at each bit position, it is possible to produce the sum for each bit position in parallel. In practice, however, this can require a large number of logic gates. Some logic gates can be removed by re-using the output signals generated for previous bits. However, this removes parallelism and therefore increases the execution time.

One technique that can be used is to group the bits of an addition operation into groups of four bits and performing the addition on each group of bits separately. For instance, the above vectors A and B could instead be split to produce A_{UPPER}=[1,1,0,1], A_{LOWER}=[1,0,1,0], B_{UPPER}=[1,1,1,1], and B_{LOWER}=[0,0,1,1]. At the final stages of the addition, the additions can be merged together, with bits being accorded their appropriate significance and a carry-out from one group being passed as a carry-in to a next group. In the following descriptions of figures, it is assumed that such a technique is used—however, this is not essential.

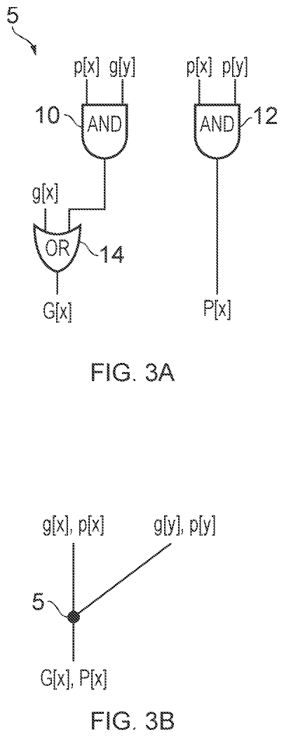

FIG. 3A shows a generalisation of the prefix node 5 shown in FIG. 2A. In particular, in this generalisation there is no requirement for the two input bit positions to be adjacent. The inputs therefore may be p[x], g[x] and p[y], g[y], where y<x. In this situation, essentially the same operation is performed using a pair of logical AND gates 10, 12 and a logical OR gate 14 as that shown in FIG. 2A. The output is referred to as G[x], P[x], which are group functions over a contiguous range.

$$G [ x ] , P [ x ] = ( g [ x ] , p [ x ] ) \cdot ( g [ x - 1 ] , p [ x - 1 ] ) \cdot$$

(contiguously, back to a given bit position) FIG. 3B shows an alternative representation of the prefix node 5 of FIG. 3A.

In this figure, the generate g[x] and propagate signals p[x] for a given bit position x are provided as a pair g[x], p[x] to a node. The function of the prefix node 5 illustrated by a circle is equivalent to the series of logic gates 10, 12, and 14 illustrated in FIG. 3A.

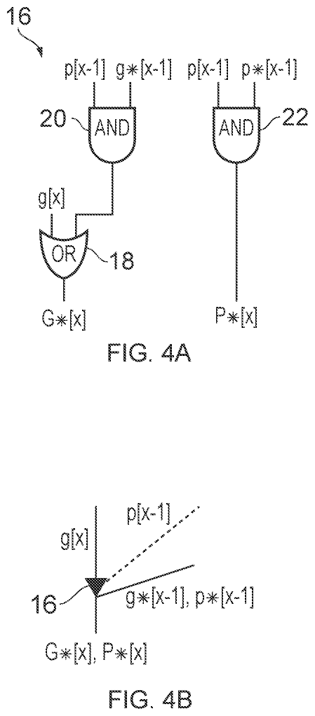

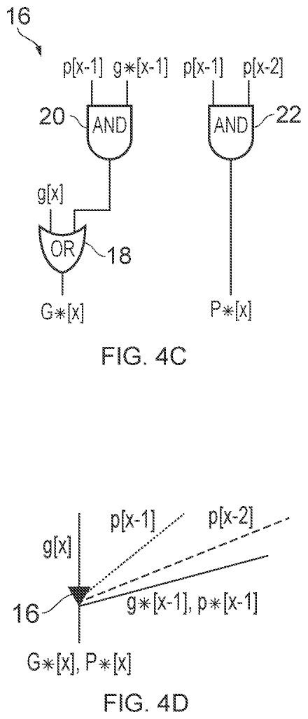

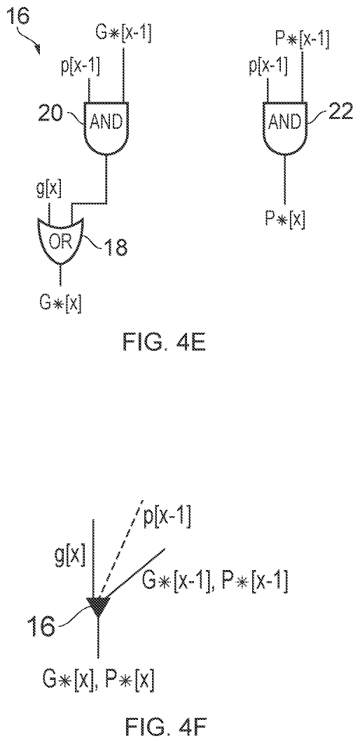

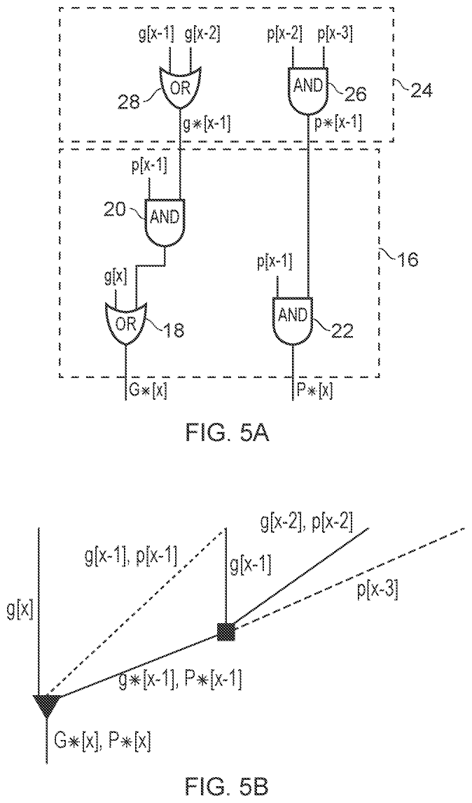

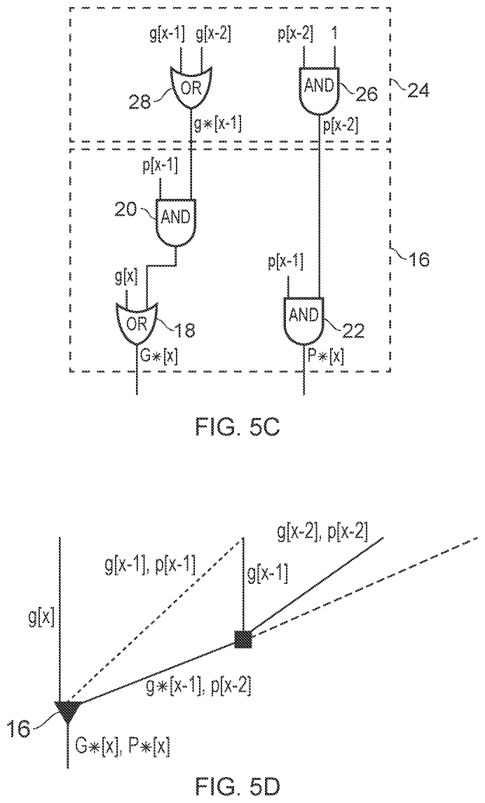

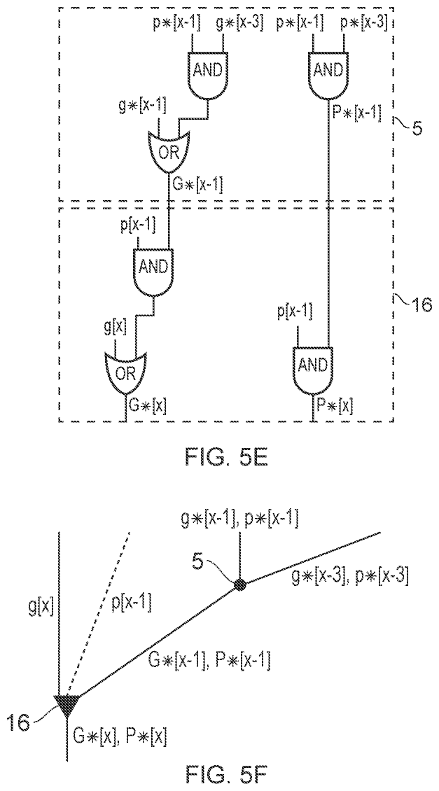

FIG. 4A illustrates an apparatus 16. The apparatus 16 comprises a first AND gate 22 that performs a logical AND operation between the propagate signal of a previous bit position p[x−1] and a partial propagate star signal of a previous bit position p*[x−1]. The nature of the partial propagate star signal here will be illustrated with respect to FIGS. 5A and 5B but in summary can be thought of as a signal that indicates whether a contiguous set of at least two previous bit positions were carry propagators. The first AND gate 22 therefore produces the signal P*[x] (i.e. it lacks p[x]). The signal P*[x] represents whether the contiguous set of previous bit positions up to bit position x−1 conditionally propagates a carry-out signal (i.e. in dependence on the carry-in signal) at position x. That is, P[x]=P*[x]& p[x].

The apparatus also includes an interlinked second logical AND gate 20 and OR gate 18. The second logical AND gate 20 performs a logical AND operation between p[x−1], the propagate signal of the previous bit position and a partial generate star signal of a previous bit position g*[x−1]. Again, the nature of the partial generate star signal here will be illustrated with respect to FIGS. 5A and 5B but in summary can be thought of as a signal that indicates whether a contiguous set of at least two previous bit positions conditionally produce a carry-out signal. The OR gate 18 is used to perform a logical OR operation between the output of the second logical AND gate 20 and g[x]. Consequently, the second logical AND gate 20 and the logical OR gate 18 collectively generate G*[x]. The signal G*[x] represents whether a contiguous set of previous bit positions up to bit position x conditionally causes generation of a carry-out signal at position x. That is, G[x]=G*[x]& p[x].

FIG. 4B illustrates a different representation of this circuitry. In this figure, the generate g[x] and propagate signals p[x] for a given bit position are available as a pair g[x], p[x] to the apparatus 16 together with the generate and propagate signals from an immediately previous bit position g[x−1], p[x−1], and the partial propagate star signal and partial generate star signal from the immediately previous bit position g*[x−1], p*[x−1]. The function of the node 16 illustrated by a triangle is equivalent to the series of logic gates 18, 20, 22 illustrated in FIG. 4A.

FIG. 4C illustrates the apparatus 16, which can also take a simplified set of inputs. In particular, since p*[x−1]=p[x−2]& p[x−3] then when p[x−3]=1, p*[x−1] simplifies to p[x−2]. Thus, if it can be assumed that p[x−3]=1 (as may occur across a byte boundary for instance), then a simpler input can be provided. Thus, the first AND gate 22 performs a logical AND operation between p[x−1] and p[x−2]. The result is still P*[x]. The second AND gate 20 and the OR gate 18 remain unchanged. Thus, the partial propagate star signal is simplified to p[x−2].

FIG. 4D illustrates the simplified operation in a form corresponding to that of FIG. 4B. In particular, the apparatus 16 receives g*[x−1] from a connected node 24, but does not receive p*[x−1] from that connected node 24. Rather, it receives p[x−2] corresponding to FIG. 4C.

FIG. 4E shows a variant in which the apparatus 16 is connected to one type of node 5 rather than another type of node 24. Here, the first AND gate 22 performs a logical AND operation between the propagate signal of a previous bit position p[x−1] and a slightly different partial propagate star signal of a previous bit position P*[x−1]. The nature of the partial propagate star signal here will be illustrated with respect to FIGS. 5E and 5F but in summary can be thought of as a signal that indicates whether a contiguous set of (two or more) previous bit positions were carry propagators.

Also in FIG. 4E is an interlinked AND gate 20 and OR gate 18. Here, the AND gate 20 takes a slightly different partial generate star signal of a previous bit position G*[x−1]. The nature of this signal will be shown with respect to FIGS. 5E and 5F but in summary can be thought of as a signal that indicates whether a contiguous set of (two or more) previous bit positions collectively yield a generated carry.

FIG. 4F illustrates the simplified operation in a form corresponding to that of FIG. 4B. In particular, the apparatus 16 is shown as being connected to a node 5 that generates G*[x−1], P*[x−1].

FIG. 5A illustrates the apparatus 16 of FIG. 4A in context, together with a Ling partial carry node 24 (described for instance in “High Speed Binary Parallel Adder”, H. Ling, 1966 IEEE, “High-Speed Binary Adder”, H. Ling, 1981 IBM J Res Dev V25 No3, and “High-Speed Parallel-Prefix VLSI Ling Adders”, G. Dimitrakopoulos & D. Nikolos, 2005 IEEE Tran on Comp, the contents of which are incorporated herein in their entirety) comprising logic gates 26, 28 that are used to generate the partial propagate star signal p*[x−1] and the partial generate star signal g*[x−1] (again, assuming that the vectors are split into groups of 4 bits). An OR gate 28 is used to test whether the preceding bit position x−1 unconditionally generates a carry-out signal or whether the bit position prior to that x−2 unconditionally generates a carry-out signal. Meanwhile, an AND gate 26 is used to determine whether the bit position x−2 and the bit position x−3 both propagate a carry-in signal to become a carry-out signal.

FIG. 5B illustrates another representation of this circuitry, with the Ling partial carry node 24 being illustrated as a square.

FIG. 5C shows the variant corresponding to FIG. 4C, which is when p[x−3] falls before the vector boundary (e.g. x<3). In this situation, the value of p[x−3] can be simplified to ‘1’ and therefore the output of AND gate 26 is equivalent to p[x−2] and so this forms the second input to AND gate 22.

Note that although an AND gate 26 is shown in this example, it will be appreciated that technically speaking it serves no purpose, since the output of the AND gate 26 is simply the remaining input—p[x−2].

FIG. 5D shows the alternative representation (similar to that of FIG. 5B) for the variant of the circuit shown in FIG. 5C.

FIG. 5E corresponds to the variant shown in FIG. 4E where the apparatus 16 is connected to a prefix node 5 that generates G*[x−1] and P*[x−1] as the partial generate star signal and partial propagate star signal.

FIG. 5F shows the corresponding alternative view of FIG. 5E.

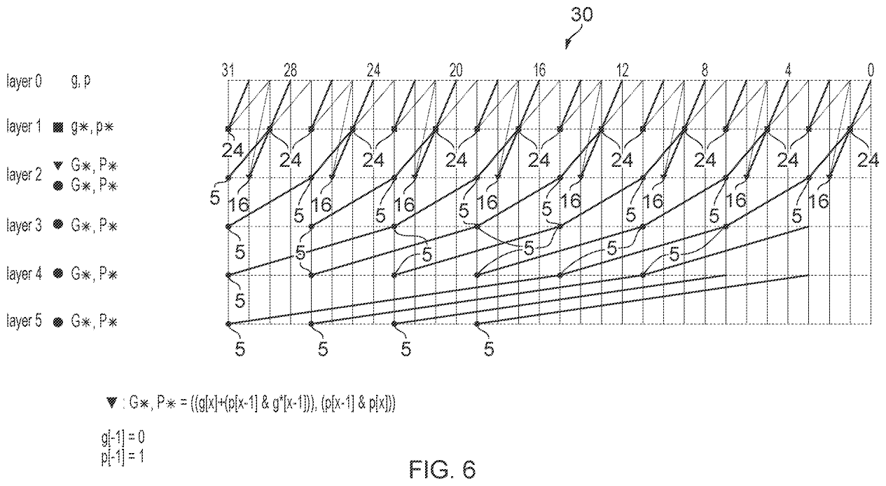

FIG. 6 illustrates an example in which the apparatus 16 (illustrated by a triangle), particularly of the forms shown in FIGS. 4A, 4B, 4C, 4D, 5A, 5B, 5C, and 5D, is used in adder circuitry 30. In this case, the adder circuitry 30 is a 32-bit adder and is arranged as a number of layers (layer 0 to layer 5). At a first layer (layer 0), the g and p signals are generated for each bit position 0 . . . 31. In a next layer, (g*, p*) signals are generated. A (g*, p*) signal is produced by a Ling partial carry node 24 for every second bit position (e.g. at bit positions 1, 3, 5, 7, . . . ). The value g*[x] represents the logical OR of g[x] with g[x−1] and the value p*[x] represents the logical AND of p[x−1] with p[x−2]. The production of the (g*, p*) signals by Ling partial carry nodes 24 at every second bit position (rather than at every bit position) is possible because of the apparatus 16, which is provided in the third layer (layer 2). This is possible, in part, because placing a Ling partial carry at the second bit position would be substantially idempotent. It is sufficient for the apparatus 16 to receive g[2], p[1], and p[0] rather than g*[2], p*[2]. Removing the node 24 at each second bit position (in each group of four bits) reduces the logic gates/power required for layer 1 by 50%, improving speed by reduction of area, and wire complexity while contributing little to no negative impact. The apparatus 16 therefore completes the Ling carry look-ahead calculation required for the 4-bit interval sum.

The apparatuses 16 are organised in the adder circuitry 30 in layer 2 so that, within each block of four bits, no (g*, p*) signal is generated for bit 0, a (g*, p*) signal is generated for bit 1, the apparatus 16 is provided for bit 2, and a (g*, p*) signal is generated by a Ling partial carry node 24 for bit 3.

Also in layer 2 are the nodes 5 that provide G*[x] and P*[x] as previously described. Note that whereas the use of these nodes 5 previously provided G[x] and P[x], the presence of the Ling partial carry nodes 24 means that the output of these nodes 5 is G*I[x] and P*[x].

Layers 3 to 5 of the adder circuitry 30 then combine the groups of bits together in a ‘binary-tree’ like manner using the prefix nodes 5. Specifically, the layers form a sparse-4 prefix graph. That is, neighbouring pairs of four-bit groups are combined in layer 3. Then the resulting combined 8-bit groups are combined in layer 4 to produce combined 16-bit groups. Finally, the two resulting 16-bit groups are combined in layer 5. This results in a G*, P* signal that is propagated at each bit position up to G*[31], P*[31].

The use of the Ling partial carry nodes 24 that generate the (g*, p*) signal at the second layer makes it possible to reduce the delay of a critical path of the overall adder circuitry. In particular, if bits are dealt with in 4-bit chunks then the equation for determining G[3] would be:

$$G [ 3 ] = g [ 3 ] + g [ 2 ] p [ 3 ] + g [ 1 ] p [ 2 ] p [ 3 ] + g [ 0 ] p [ 1 ] p [ 2 ] p [ 3 ]$$

$$Or$$

$$G [ 3 ] = g [ 3 ] + p [ 3 ] ( g [ 2 ] + p [ 2 ] ( g [ 1 ] + g [ 0 ] p [ 1 ] ) )$$

This requires a large number of transistors, which can lead to a long critical path. Instead, the Ling partial carry nodes 24 generate the (g*, p*) signals, which allows the G[4] equation to be simplified. For example, this can be done by factoring out the p[3] term until the final sum bit formation. In other examples, the Ling partial carries may enable a different parameter to be removed from the critical path such as a XOR gate, as described in “High-Speed Parallel-Prefix VLSI Ling Adders”, G. Dimitrakopoulos & D. Nikolos, 2005 IEEE Tran on Comp.

This particular adder circuitry 30 uses a total of N(log₂(N)+1)/4+1 nodes 5, 16, 24 to perform addition of an N-bit number. Furthermore, addition is performed with a prefix delay of log₂(N)—that is, the total number of nodes 5, 16, 24 through which the signals pass in the adder circuitry 30 is log₂(N).

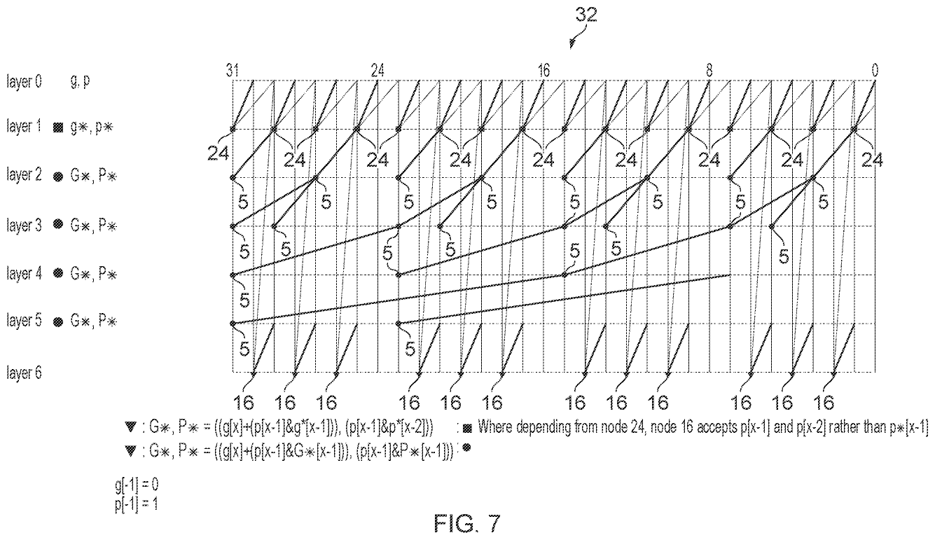

FIG. 7 shows an alternative implementation of the adder circuitry 32 in which the apparatus takes the form shown in FIGS. 4E, 4F, 5E, and 5F. In this embodiment, bits are considered together in blocks of 8 bits and the apparatuses 16 are placed in a final layer (layer 6) of the adder 32 and in some instances, take slightly different inputs as will be discussed.

The first two layers of the adder 32 are the same as for the adder 30 described with reference to FIG. 6. The third layer (layer 2) is the same except for the removal of the apparatuses 16 (which have been moved to layer 6). Layers 2 to 5 again merge the inputs together. Finally, the apparatuses 16 in the final layer (6 in this example) complete the process by compensating for a reduced number of Ling partial carry nodes 24 in layer 1. Ling partial carry nodes 24 at bits [6,4,2] (in each block of 8 bits) would be substantially idempotent. It is sufficient for the nodes 16 at bits [6,4,2] (in each block of 8 bits) to receive g[6,4,2], p[5,3,1], rather than g*[6,4,2], p*[6,4,2]. Note that the nodes 16 in layer 6 at bits [6,4] (in each block of 8 bits) receive G*[5,3], P*[5,3] whereas the nodes 16 in layer 6 at bit [2] (in each block of 8 bits) receives g*[1], p[1], p[0] rather than g*[1] with p*[1].

Also, layer 1 Ling partial carry nodes located at bit 1 in each byte receive p[i−1] and p[i−2] crossing the byte boundary as required to correctly calculate the sparse-8 parallel prefix carry look-ahead. As shown in FIG. 7, the value of p[<0] (for the overall adder, rather than for each block of 8 bits) for the first byte is 1.

Thus, inputs to the nodes 16 located at bit 2 in each byte are simplified according to this required byte sum functionality.

More generally, the structure shown in FIG. 7 resembles a sparse-8 parallel prefix carry look ahead graph. To this, 4 nodes are added to each contiguous byte, to complete logic for bit lane carry outputs. For adders of more than 32 bits, this balances the delay to produce [G*, P*] out of each bit lane (roughly 4 complex AND-OR gate delays) against the delay to produce the sparse-8 carry look-ahead outputs, which is Log₂(N bits). The sparse-8 outputs arrive soon after bit lane [G*, P*] outputs, providing improved overall performance in adders more than 32 bits wide.

Each 8-bit interval provides carry lookahead to form a Sum & (Sum+1) calculation using the [G*, P*] bit lane outputs, and one of these is chosen according to the carry input to the LSB of those 8 bits provided by the sparse-8 (overall) carry look-ahead calculation of [G*, P*].

In this example, the inputs to the apparatus 16 can vary. For each block of 8 bits, three apparatuses 16 are provided—one at a third bit position, one at a fifth bit position, and one at a seventh bit positon. In each case, the generate and propagate bits for the current bit position x and the immediately preceding bit position (x−1) are received, with the generate bit for the current bit position g[x] and the propagate bit for the immediately preceding bit position, p[x−1] being used. The apparatus at the third bit position receives an input from a ling partial carry node 24 in a similar manner to that shown in FIG. 6. In contrast, the remaining two apparatuses (at the fifth and seventh bit positions) take inputs from general prefix nodes 5 (of the type shown in FIGS. 3A and 3B) in layer 2 and layer 3 respectively.

The adder illustrated in FIG. 7 makes use of an extra layer. However, the total number of nodes 5, 16, 24 through which a signal passes remains the same—log₂(N) for N>=16.

This adder 32 uses N(log₂(N)+7)/8+1 prefix nodes and performs addition of a 32-bit number with a log₂(N) prefix delay. In practice, therefore, this adder 32 requires fewer logic gates for performing additions where N>32. In contrast, the adder 30 shown in FIG. 6 requires fewer logic gates for performing additions where N<32. Thus, for an adder that is designed to add only 16-bit numbers, the adder of FIG. 6 will use fewer logic gates and for an adder that is designed to add 64-bit numbers, the adder of FIG. 7 would be the better choice. In either case, the delay is log₂(N).

Although the apparatus 16 has been illustrated as being useful for reducing the number of Ling partial carry nodes 24, this is not the only use of the apparatus 16. In particular, the apparatus 16 is also useful in adder circuits where carry select techniques are used. Such adders may or may not make use of Ling partial carry nodes 24. In particular, in a carry select adder, the values (sum) and (sum+1) are calculated for each group of bits. For instance, for each group of four bits. These two values are calculated in parallel. A multiplexer is then used to select between the two values and the selection signal is based on whether a carry-in signal is provided to that group. For instance, if the carry-in signal is 1 then the value (sum+1) is provided. If the carry-in signal is 0 then the value (sum) is provided. It will be appreciated that the previously described techniques can be used to determine whether a carry-in signal is provided for a group of bits.

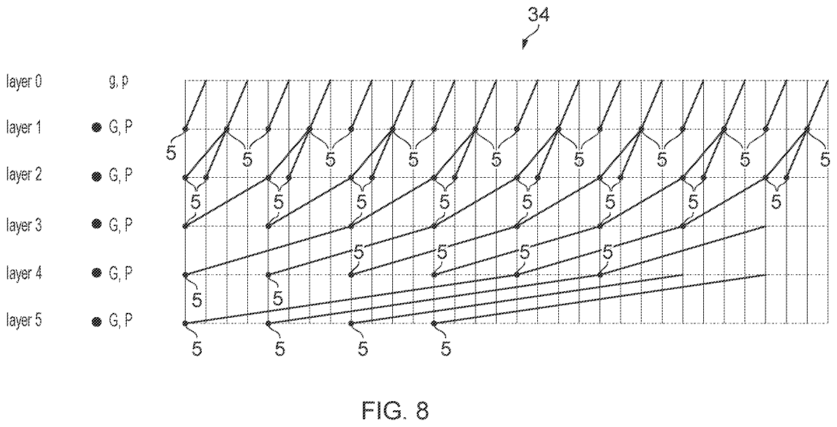

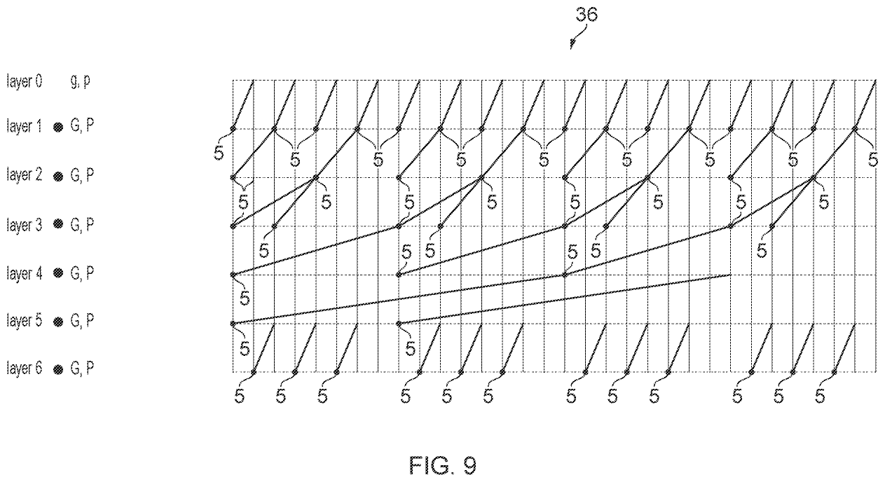

The present techniques are not only applicable to carry lookahead adders using Ling partial nodes 24. In particular, non-Ling adder variants are illustrated in FIGS. 8 and 9.

FIG. 8 shows a non-Ling diagrammatic variant 34 of the adder circuitry 30 shown in FIG. 6. In this network, all of the nodes 5, 16, 24 have been replaced by prefix nodes 5. The adder 32 is diagrammatic in the sense that it conceptually represents how signals are passed between nodes. In practice, of course, synthesis of a circuit may cause the signals to actually be passed in a different physical manner that is considered to be more efficient by the automated synthesis tool. Nevertheless, the resulting adder circuitry would be necessarily considered to be logically equivalent such that for any set of inputs the same set of outputs would be produced between the diagrammatic version and the synthesised one.

As with the adder 30 of FIG. 6, the network 34 is made up of a number of layers. A first layer (layer 1) of the network receives the generate and propagate signals that are generated for each bit position (in this example, generated by a special ‘layer 0’ for completeness). At each layer, inputs are combined by further prefix nodes 5. Either generate and propagate signals are merged together for two bit positions, or outputs from other prefix nodes from a previous layer are merged together (the output of each prefix node having a generate and propagate signal), or a generate and propagate signal are merged with the output of another prefix node from a previous layer. In the first layer, prefix nodes are at every second bit position (e.g. bit position 0 has no prefix node, but bit position 1 does, and then bit position 2 does not and so on). In a second layer, the prefix nodes are at every fourth bit position and merge outputs from adjacent prefix nodes in the first layer. Also in the second layer, further prefix nodes are located at a bit position one before the previously mentioned nodes in the second layer. These nodes take the generate and propagate signals for the current position and merge these with the prefix node at the previous bit position. In the third layer, pairs of adjacent prefix nodes found at every fourth position of the second layer are merged in a dovetailed fashion. Layers 4 and 5 (the final layer), are merging group (G,P) derived from contiguous, non-overlapping subranges of bit positions, hierarchically.

In FIG. 8, a 32-bit adder 30 is illustrated. In practice, this adder and that of FIG. 6 can be scaled up or down in tiles of 4 bits and scaling the adder 30 in this way changes a number of layers in the adder 30. Here we disregard layer 0 that generates the g and p signals. In particular, layer 1 is used to merge pairs of inputs together. Layer 2 then merges the merged pairs and provides additional nodes (one bit position before the node that does the merging of the merged pairs). In particular, at layer 2 bit position 2 and every 4th bit position greater, logic node 5 combines respective bitwise generate and propagate inputs g and p from layer 0 with group generate and propagate signals G and P provided by logic node 5 at bit position 1 and every 4th bit position greater, to form the final group generate and propagate signals G and P for bit position 2 and every 4th bit position greater.

There are then (log₂(M)−2) layers after the second layer (layer 2) to merge the outputs together. So for a 32-bit adder, there are three layers (layers 3, 4, and 5) after the second layer (layer 2). Note that this scaling also applies to FIG. 6, where some of the prefix nodes 5 in the second layer are replaced by the apparatus 16.

FIG. 9 shows the other non-Ling diagrammatic variant 36 of the adder circuitry 32 shown in FIG. 7. In this network, all of the nodes 5, 16, 24 have been replaced by prefix nodes 5. The adder 36 is diagrammatic in the sense that it conceptually represents how signals are passed between nodes. In practice, of course, synthesis of a circuit may cause the signals to actually be passed in a different physical manner that is considered to be more efficient by the automated synthesis tool. Nevertheless, the resulting adder circuitry would be considered to be logically equivalent such that for any set of inputs the same set of outputs would be produced between the diagrammatic version and the synthesised one.

As with the adder 32 of FIG. 7, the network 36 is made up of a number of layers. A first layer (layer 1) of the network receives the generate and propagate signals that are generated for each bit position (in this example, generated by a special ‘layer 0’ for completeness). At each layer, inputs are combined by further prefix nodes 5. Either generate and propagate signals are merged together for two bit positions, or outputs from other prefix nodes from a previous layer are merged together (the output of each prefix node having a generate and propagate signal), or a generate and propagate signal are merged with the output of another prefix node from a previous layer. In the first layer, prefix nodes are at every second bit position (e.g. bit position 0 has no prefix node, but bit position 1 does, and then bit position 2 does not and so on). In a second layer, the prefix nodes are at every fourth bit position and merge outputs from adjacent prefix nodes in the first layer. Then in the third layer, prefix nodes are at every eighth position and merge outputs from adjacent prefix nodes in the second layer. Also in the third layer, further prefix nodes are present a bit position two away from the prefix nodes at every eighth position. In the fourth layer, located at bit position 15 and every 8^{th} bit position greater, prefix nodes 5 merge adjacent byte-wise group carry look-ahead G and P values provided by layer 3 prefix nodes 5 located at bit position 7 and every 8^{th} bit position greater, to construct 16-bit group carry look-ahead G and P values, in an overlapping pattern. In the fifth layer, located at bit position 23 and every 8^{th} bit position greater, prefix nodes 5 individually merge non-overlapping group carry look-ahead G and P values for contiguous bit ranges not exceeding 32 bits in order to further construct an 8 sparse carry look-ahead prefix graph. At a final layer, prefix nodes 5 located at bit position 2 and every 2^{nd} bit position greater merge their respective input propagate (p) and generate (g) signals with intra-byte group carry look-ahead G and P values provided by other prefix nodes 5 within their respective 8-bit subrange, counted from bit position 0.

In FIG. 9, a 32-bit adder 36 is illustrated. In practice, this adder and the adder of FIG. 7 can be scaled up or down in tiles of 8 bits and scaling the adder 36 in this way changes a number of layers in the adder 36. Here we disregard layer 0 that generates the g and p signals. In particular, layer 1 is used to merge pairs together. Layer 2 then merges the pairs and layer 3 merges the merged pairs into eights. With a single 8-bit tile, a final layer can then be added. In other examples, there are (log₂(M)−3) layers between the third layer (layer 3) and the final layer. So for a 32-bit adder, there are two layers (layers 4 and 5) between the third layer (layer 3) and the last layer (layer 6).

The techniques above therefore can therefore result in a better computer through providing an apparatus 16 that can reduce the need for some other nodes and through particular topologies that produce a good combination of depth (affecting calculation time), population (affecting circuit area), and fan-out (affecting time/delay at each stage).

Concepts described herein may be embodied in a system comprising at least one packaged chip. The apparatus and/or adder described earlier is implemented in the at least one packaged chip (either being implemented in one specific chip of the system, or distributed over more than one packaged chip). The at least one packaged chip is assembled on a board with at least one system component. A chip-containing product may comprise the system assembled on a further board with at least one other product component. The system or the chip-containing product may be assembled into a housing or onto a structural support (such as a frame or blade).

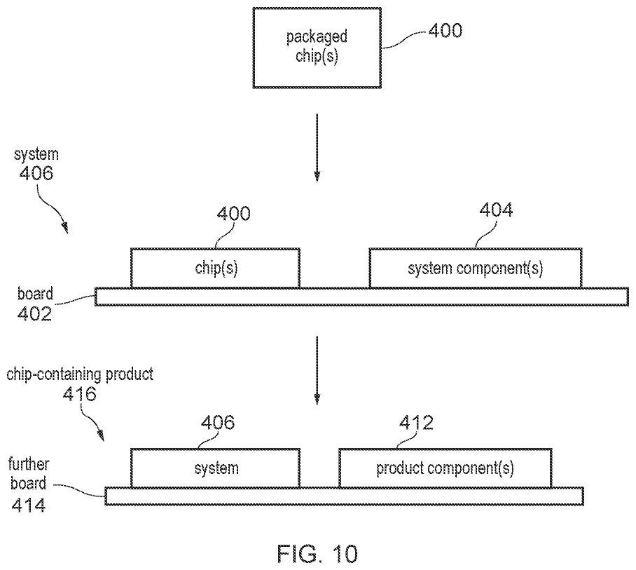

As shown in FIG. 10, one or more packaged chips 400, with the apparatus and/or adder described above implemented on one chip or distributed over two or more of the chips, are manufactured by a semiconductor chip manufacturer. In some examples, the chip product 400 made by the semiconductor chip manufacturer may be provided as a semiconductor package which comprises a protective casing (e.g. made of metal, plastic, glass or ceramic) containing the semiconductor devices implementing the apparatus and/or adder described above and connectors, such as lands, balls or pins, for connecting the semiconductor devices to an external environment. Where more than one chip 400 is provided, these could be provided as separate integrated circuits (provided as separate packages), or could be packaged by the semiconductor provider into a multi-chip semiconductor package (e.g. using an interposer, or by using three-dimensional integration to provide a multi-layer chip product comprising two or more vertically stacked integrated circuit layers).

In some examples, a collection of chiplets (i.e. small modular chips with particular functionality) may itself be referred to as a chip. A chiplet may be packaged individually in a semiconductor package and/or together with other chiplets into a multi-chiplet semiconductor package (e.g. using an interposer, or by using three-dimensional integration to provide a multi-layer chiplet product comprising two or more vertically stacked integrated circuit layers).

The one or more packaged chips 400 are assembled on a board 402 together with at least one system component 404 to provide a system 406. For example, the board may comprise a printed circuit board. The board substrate may be made of any of a variety of materials, e.g. plastic, glass, ceramic, or a flexible substrate material such as paper, plastic or textile material. The at least one system component 404 comprise one or more external components which are not part of the one or more packaged chip(s) 400. For example, the at least one system component 404 could include, for example, any one or more of the following: another packaged chip (e.g. provided by a different manufacturer or produced on a different process node), an interface module, a resistor, a capacitor, an inductor, a transformer, a diode, a transistor and/or a sensor.

A chip-containing product 416 is manufactured comprising the system 406 (including the board 402, the one or more chips 400 and the at least one system component 404) and one or more product components 412. The product components 412 comprise one or more further components which are not part of the system 406. As a non-exhaustive list of examples, the one or more product components 412 could include a user input/output device such as a keypad, touch screen, microphone, loudspeaker, display screen, haptic device, etc.; a wireless communication transmitter/receiver; a sensor; an actuator for actuating mechanical motion; a thermal control device; a further packaged chip; an interface module; a resistor; a capacitor; an inductor; a transformer; a diode; and/or a transistor. The system 406 and one or more product components 412 may be assembled on to a further board 414.

The board 402 or the further board 414 may be provided on or within a device housing or other structural support (e.g. a frame or blade) to provide a product which can be handled by a user and/or is intended for operational use by a person or company.

The system 406 or the chip-containing product 416 may be at least one of: an end-user product, a machine, a medical device, a computing or telecommunications infrastructure product, or an automation control system. For example, as a non-exhaustive list of examples, the chip-containing product could be any of the following: a telecommunications device, a mobile phone, a tablet, a laptop, a computer, a server (e.g. a rack server or blade server), an infrastructure device, networking equipment, a vehicle or other automotive product, industrial machinery, consumer device, smart card, credit card, smart glasses, avionics device, robotics device, camera, television, smart television, DVD players, set top box, wearable device, domestic appliance, smart meter, medical device, heating/lighting control device, sensor, and/or a control system for controlling public infrastructure equipment such as smart motorway or traffic lights.

Concepts described herein may be embodied in computer-readable code for fabrication of an apparatus that embodies the described concepts. For example, the computer-readable code can be used at one or more stages of a semiconductor design and fabrication process, including an electronic design automation (EDA) stage, to fabricate an integrated circuit comprising the apparatus embodying the concepts. The above computer-readable code may additionally or alternatively enable the definition, modelling, simulation, verification and/or testing of an apparatus embodying the concepts described herein.

For example, the computer-readable code for fabrication of an apparatus embodying the concepts described herein can be embodied in code defining a hardware description language (HDL) representation of the concepts. For example, the code may define a register-transfer-level (RTL) abstraction of one or more logic circuits for defining an apparatus embodying the concepts. The code may define a HDL representation of the one or more logic circuits embodying the apparatus in Verilog, SystemVerilog, Chisel, or VHDL (Very High-Speed Integrated Circuit Hardware Description Language) as well as intermediate representations such as FIRRTL. Computer-readable code may provide definitions embodying the concept using system-level modelling languages such as SystemC and SystemVerilog or other behavioural representations of the concepts that can be interpreted by a computer to enable simulation, functional and/or formal verification, and testing of the concepts.

Additionally or alternatively, the computer-readable code may define a low-level description of integrated circuit components that embody concepts described herein, such as one or more netlists or integrated circuit layout definitions, including representations such as GDSII. The one or more netlists or other computer-readable representation of integrated circuit components may be generated by applying one or more logic synthesis processes to an RTL representation to generate definitions for use in fabrication of an apparatus embodying the invention. Alternatively or additionally, the one or more logic synthesis processes can generate from the computer-readable code a bitstream to be loaded into a field programmable gate array (FPGA) to configure the FPGA to embody the described concepts. The FPGA may be deployed for the purposes of verification and test of the concepts prior to fabrication in an integrated circuit or the FPGA may be deployed in a product directly.

The computer-readable code may comprise a mix of code representations for fabrication of an apparatus, for example including a mix of one or more of an RTL representation, a netlist representation, or another computer-readable definition to be used in a semiconductor design and fabrication process to fabricate an apparatus embodying the invention. Alternatively or additionally, the concept may be defined in a combination of a computer-readable definition to be used in a semiconductor design and fabrication process to fabricate an apparatus and computer-readable code defining instructions which are to be executed by the defined apparatus once fabricated.

Such computer-readable code can be disposed in any known transitory computer-readable medium (such as wired or wireless transmission of code over a network) or non-transitory computer-readable medium such as semiconductor, magnetic disk, or optical disc. An integrated circuit fabricated using the computer-readable code may comprise components such as one or more of a central processing unit, graphics processing unit, neural processing unit, digital signal processor or other components that individually or collectively embody the concept.

The present technique could also be configured as follows:
1. An apparatus comprising:
a plurality of logic gates used in an addition of a first vector of bits to a second vector of bits, the plurality of logic gates being configured to receive four inputs comprising:
a generate signal configured to indicate whether the addition at a first bit position would unconditionally produce a carry-out signal at the first bit position;
a propagate signal configured to indicate whether the addition at a second bit position would conditionally produce a carry-out signal at the second bit position;
an individual partial generate star signal configured to indicate whether the addition of the first vector and the second vector at a third bit position or a fourth bit position would unconditionally produce a carry-out signal at either of the third bit position or the fourth bit position; and
an individual partial propagate star signal configured to indicate whether the addition of the first vector and the second vector at a fifth bit position and a sixth bit position would conditionally produce carry-out signals at the fifth bit position and the sixth bit position, wherein
the plurality of logic gates are configured to combine the four inputs to output an indication of whether the addition at most significant bit positions of the first vector and the second vector will unconditionally produce a carry-out signal and to output an indication of whether the addition at least significant bit positions of the first vector and the second vector will conditionally produce a carry-out signal.
2. The apparatus according to clause 1, wherein
   the second bit position is immediately prior to the first bit position.
3. The apparatus according to any preceding clause, wherein
   the third bit position is the same as the second bit position; and
   the fourth bit position is immediately prior to the third bit position.
4. The apparatus according to any preceding clause, wherein
   the fifth bit position is the same as the fourth bit position; and
   the sixth bit position is immediately prior to the fifth bit position.
5. The apparatus according to any preceding clause, wherein the plurality of logic gates are configured to receive at most the generate signal, the propagate signal, the individual partial generate star signal, and the individual partial propagate star signal.
6. The apparatus according to any preceding clause, wherein the first vector of bits represent a first number and the second vector of bits represent a second number, with the addition operation being configured to add the first number and the second number together by adding the first vector of bits to the second vector of bits.
7. The apparatus according to any preceding clause, wherein the plurality of logic gates are configured to receive the generate signal, the propagate signal, the individual partial generate star signal, and the individual partial propagate star signal as inputs from outside the plurality of logic gates.
8. The apparatus according to any preceding clause, wherein
   the plurality of logic gates is configured to perform:
a first AND function between the propagate signal and the individual partial generate star signal,
a first inclusive OR function between a result of the first AND function and the generate signal, and
a second AND function between the propagate signal and the individual partial propagate star signal
to output the indication of whether the addition at most significant bit positions of the first vector and the second vector will unconditionally produce the carry-out signal and to output the indication of whether the addition at least significant bit positions of the first vector and the second vector will conditionally produce the carry-out signal.
9. The apparatus according to clause 8, wherein
the plurality of logic gates is configured to perform at most the first AND function, the second AND function, and the first inclusive OR function to output the indication of whether the addition at most significant bit positions of the first vector and the second vector will unconditionally produce the carry-out signal and to output the indication of whether the addition at least significant bit positions of the first vector and the second vector will conditionally produce the carry-out signal.
10. An adder circuit comprising the apparatus of any preceding clause, wherein
the adder circuit is configured as a plurality of layers, with each layer other than a first layer performing an operation in parallel on different inputs from a previous layer; and the first layer is configured to generate the generate signal and the propagate signal for each bit position of the first vector of bits and the second vector of bits.
11. The adder circuit according to clause 10, wherein
a second layer of the plurality of layers comprises one or more partial carry nodes, configured to generate the individual partial generate star signal and the individual partial propagate star signal.
12. The adder circuit according to clause 11, wherein
the second layer of the plurality of layers comprises at least some holes in place of the one or more partial carry nodes such that the generate signal and the propagate signal for at least some pairs of adjacent bit positions are not provided together, as a pair of inputs, to the one or more partial carry nodes.
13. The adder circuit according to any one of clauses 11-12, wherein
the generate signal and the propagate signal for each of the bit positions is provided to the one or more partial carry nodes.
14. The adder circuit according to any one of clauses 11-13, wherein
for at least some bit positions, the generate signal or the propagate signal are provided to exactly one of the partial carry nodes.
15. A non-transitory computer-readable medium storing computer-readable code for fabrication of an apparatus comprising:
a plurality of logic gates used in an addition of a first vector of bits to a second vector of bits, the plurality of logic gates being configured to receive four inputs comprising: a generate signal configured to indicate whether the addition at a first bit position would unconditionally produce a carry-out signal at the first bit position;
a propagate signal configured to indicate whether the addition at a second bit position would conditionally produce a carry-out signal at the second bit position;
an individual partial generate star signal configured to indicate whether the addition of the first vector and the second vector at a third bit position or a fourth bit position would unconditionally produce a carry-out signal at either of the third bit position or the fourth bit position; and
an individual partial propagate star signal configured to indicate whether the addition of the first vector and the second vector at a fifth bit position and a sixth bit position would conditionally produce carry-out signals at the fifth bit position and the sixth bit position, wherein
the plurality of logic gates are configured to combine the four inputs to output an indication of whether the addition at most significant bit positions of the first vector and the second vector will unconditionally produce a carry-out signal and to output an indication of whether the addition at least significant bit positions of the first vector and the second vector will conditionally produce a carry-out signal.
16. Carry-lookahead circuitry comprising:
   a plurality of logic nodes logically arranged in a plurality of layers, each of the logic nodes performing a logical function using a plurality of interconnected logic gates, wherein the logic nodes of one layer receive at least one input from an immediately previous one of the plurality of layers;
   a first logical layer of the plurality of layers is configured to receive, in respect of each bit position for a first vector of bits and a second vector of bits:
a generate signal configured to indicate whether bits of the first vector and the second vector at that bit position would unconditionally produce a carry-out signal, and
a propagate signal configured to indicate whether bits of the first vector and the second vector at that bit position would conditionally produce a carry-out signal;
the first logical layer of the plurality of layers is configured to have one of the logic nodes at every second bit position; and
a second logical layer of the plurality of layers is configured to have one of the logic nodes at every fourth bit position and to have one of the logic nodes at a position one bit before every fourth bit position;
the carry-lookahead circuitry comprises a plurality of tiles, each comprising the plurality of logic nodes arranged as the first logical layer and the second logical layer, wherein
each of the tiles is configured to process 4 bits of the first vector of bits and the second vector of bits;
each of the tiles comprises (log₂(M)−2) further layers after the second logical layer, where M is a number of bits in a largest of the first vector of bits and the second vector of bits; and
each of the further layers reduces a number of outputs from a preceding layer to provide as inputs to a subsequent layer.
17. The carry-lookahead circuitry according to clause 16, wherein
those of the logic nodes in the first logical layer are configured to receive the generate signal and the propagate signal from a same bit position as themselves q and a previous bit position q−1; and
those of the logic nodes in the second logical layer are configured to receive inputs from outputs of the logic nodes in the first logical layer at a same bit position as themselves r and at a bit position r−2.
18. A system comprising:
the apparatus of any one of clauses 1-9, the adder circuit of any one of clauses 10-14, or the carry-lookahead circuitry of any one of clauses 16-17 implemented in at least one packaged chip;
   at least one system component; and
a board,
wherein the at least one packaged chip and the at least one system component are assembled on the board.
19. A chip-containing product comprising the system of clause 18, wherein
the system is assembled on a further board with at least one other product component.

We claim:

1. An apparatus comprising:
a plurality of logic gates used in an addition of a first vector of bits to a second vector of bits, the plurality of logic gates being configured to receive four inputs comprising:
a generate signal configured to indicate whether the addition at a first bit position would unconditionally produce a carry-out signal at the first bit position;
a propagate signal configured to indicate whether the addition at a second bit position would conditionally produce a carry-out signal at the second bit position;
an individual partial generate star signal configured to indicate whether the addition of the first vector and the second vector at a third bit position or a fourth bit position would unconditionally produce a carry-out signal at either of the third bit position or the fourth bit position; and
an individual partial propagate star signal configured to indicate whether the addition of the first vector and the second vector at a fifth bit position and a sixth bit position would conditionally produce carry-out signals at the fifth bit position and the sixth bit position, wherein
the plurality of logic gates are configured to combine the four inputs to output an indication of whether the addition at most significant bit positions of the first vector and the second vector will unconditionally produce a carry-out signal and to output an indication of whether the addition at least significant bit positions of the first vector and the second vector will conditionally produce a carry-out signal.

2. The apparatus according to claim 1, wherein
the second bit position is immediately prior to the first bit position.

3. The apparatus according to claim 1, wherein
the third bit position is the same as the second bit position; and
the fourth bit position is immediately prior to the third bit position.

4. The apparatus according to claim 1, wherein
the fifth bit position is the same as the fourth bit position; and
the sixth bit position is immediately prior to the fifth bit position.

5. The apparatus according to claim 1, wherein
the plurality of logic gates are configured to receive at most the generate signal, the propagate signal, the individual partial generate star signal, and the individual partial propagate star signal.

6. The apparatus according to claim 1, wherein
the first vector of bits represent a first number and the second vector of bits represent a second number, with the addition operation being configured to add the first number and the second number together by adding the first vector of bits to the second vector of bits.

7. The apparatus according to claim 1, wherein
the plurality of logic gates are configured to receive the generate signal, the propagate signal, the individual partial generate star signal, and the individual partial propagate star signal as inputs from outside the plurality of logic gates.

8. The apparatus according to claim 1, wherein
the plurality of logic gates is configured to perform:
a first AND function between the propagate signal and the individual partial generate star signal,
a first inclusive OR function between a result of the first AND function and the generate signal, and
a second AND function between the propagate signal and the individual partial propagate star signal
to output the indication of whether the addition at most significant bit positions of the first vector and the second vector will unconditionally produce the carry-out signal and to output the indication of whether the addition at least significant bit positions of the first vector and the second vector will conditionally produce the carry-out signal.

9. The apparatus according to claim 8, wherein
the plurality of logic gates is configured to perform at most the first AND function, the second AND function, and the first inclusive OR function to output the indication of whether the addition at most significant bit positions of the first vector and the second vector will unconditionally produce the carry-out signal and to output the indication of whether the addition at least significant bit positions of the first vector and the second vector will conditionally produce the carry-out signal.

10. An adder circuit comprising the apparatus of claim 1, wherein
the adder circuit is configured as a plurality of layers, with each layer other than a first layer performing an operation in parallel on different inputs from a previous layer; and
the first layer is configured to generate the generate signal and the propagate signal for each bit position of the first vector of bits and the second vector of bits.

11. The adder circuit according to claim 10, wherein
a second layer of the plurality of layers comprises one or more partial carry nodes, configured to generate the individual partial generate star signal and the individual partial propagate star signal.

12. The adder circuit according to claim 11, wherein
the second layer of the plurality of layers comprises at least some holes in place of the one or more partial carry nodes such that the generate signal and the propagate signal for at least some pairs of adjacent bit positions are not provided together, as a pair of inputs, to the one or more partial carry nodes.

13. The adder circuit according to claim 11, wherein
the generate signal and the propagate signal for each of the bit positions is provided to the one or more partial carry nodes.

14. The adder circuit according to claim 11, wherein
for at least some bit positions, the generate signal or the propagate signal are provided to exactly one of the partial carry nodes.

15. A non-transitory computer-readable medium storing computer-readable code for fabrication of an apparatus comprising:
a plurality of logic gates used in an addition of a first vector of bits to a second vector of bits, the plurality of logic gates being configured to receive four inputs comprising:
a generate signal configured to indicate whether the addition at a first bit position would unconditionally produce a carry-out signal at the first bit position;
a propagate signal configured to indicate whether the addition at a second bit position would conditionally produce a carry-out signal at the second bit position;
an individual partial generate star signal configured to indicate whether the addition of the first vector and the second vector at a third bit position or a fourth bit position would unconditionally produce a carry-out signal at either of the third bit position or the fourth bit position; and
an individual partial propagate star signal configured to indicate whether the addition of the first vector and the second vector at a fifth bit position and a sixth bit position would conditionally produce carry-out signals at the fifth bit position and the sixth bit position, wherein
the plurality of logic gates are configured to combine the four inputs to output an indication of whether the addition at most significant bit positions of the first vector and the second vector will unconditionally produce a carry-out signal and to output an indication of whether the addition at least significant bit positions of the first vector and the second vector will conditionally produce a carry-out signal.

16. Carry-lookahead circuitry comprising:
a plurality of logic nodes logically arranged in a plurality of layers, each of the logic nodes performing a logical function using a plurality of interconnected logic gates, wherein the logic nodes of one layer receive at least one input from an immediately previous one of the plurality of layers;
a first logical layer of the plurality of layers is configured to receive, in respect of each bit position for a first vector of bits and a second vector of bits:
a generate signal configured to indicate whether bits of the first vector and the second vector at that bit position would unconditionally produce a carry-out signal, and
a propagate signal configured to indicate whether bits of the first vector and the second vector at that bit position would conditionally produce a carry-out signal;
the first logical layer of the plurality of layers is configured to have one of the logic nodes at every second bit position; and
a second logical layer of the plurality of layers is configured to have one of the logic nodes at every fourth bit position and to have one of the logic nodes at a position one bit before every fourth bit position;
the carry-lookahead circuitry comprises a plurality of tiles, each comprising the plurality of logic nodes arranged as the first logical layer and the second logical layer, wherein
each of the tiles is configured to process 4 bits of the first vector of bits and the second vector of bits;
each of the tiles comprises (log₂(M)−2) further layers after the second logical layer, where M is a number of bits in a largest of the first vector of bits and the second vector of bits; and
each of the further layers reduces a number of outputs from a preceding layer to provide as inputs to a subsequent layer.

17. The carry-lookahead circuitry according to claim 16, wherein
those of the logic nodes in the first logical layer are configured to receive the generate signal and the propagate signal from a same bit position as themselves q and a previous bit position q−1; and
those of the logic nodes in the second logical layer are configured to receive inputs from outputs of the logic nodes in the first logical layer at a same bit position as themselves r and at a bit position r−2.

18. The apparatus according to claim 1 implemented in at least one packaged chip comprising:
at least one system component; and
a board,
wherein the at least one packaged chip and the at least one system component are assembled on the board.

19. A chip-containing product comprising the system of claim 18, wherein
the system is assembled on a further board with at least one other product component.
